(19) United States
(12) Patent Application Publication
(10) Pub. No.: US 2024/0090296 A1
(43) Pub. Date: Mar. 14, 2024

(54) DISPLAY PANEL WITH PIXEL LAYOUT CAPABLE OF IMPROVING GRAININESS OF PIXEL

(71) Applicant: WUHAN CHINA STAR OPTOELECTRONICS SEMICONDUCTOR DISPLAY TECHNOLOGY CO., LTD., Wuhan (CN)

(72) Inventor: Bo LI, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 18/458,282

(22) Filed: Aug. 30, 2023

(30) Foreign Application Priority Data
Sep. 9, 2022 (CN) 202211098683.X

(51) Int. Cl. H10K 59/35

(52) U.S. Cl. CPC H10K 59/353

(57) ABSTRACT

A display panel includes a plurality of pixel repeating units. Each of the pixel repeating units includes a first repeating unit. The first repeating unit includes a first sub-pixel, a second sub-pixel, and two third sub-pixels for displaying different colors. In the first repeating unit, a center of the first sub-pixel, a center of the second sub-pixel, and centers of the two third sub-pixel form a first virtual quadrilateral, with the two third sub-pixels located at diagonal corners of the first virtual quadrilateral.

### CROSS REFERENCE TO RELATED APPLICATION

This application claims priority to Chinese Application No. 202211098683.X, filed on Sep. 9, 2022. The entire disclosure of the above application is incorporated herein by reference.

### FIELD OF THE INVENTION

The present disclosure relates to the field of display technology, more particularly, to a display panel.

### BACKGROUND

An organic light emitting diode (OLED) display panel is one of the hotspots in the field of flat panel display panel research. Compared with liquid crystal displays, OLED display panels have advantages such as low energy consumption, low production cost, self-illumination, wide viewing angle, and fast response speed. Currently, in the field of flat panel displays such as handheld devices, personal digital assistants (PDA), digital cameras, etc. OLED display devices have begun to replace traditional liquid crystal displays (LCDs).

The structure of an OLED display panel comprises a substrate and pixels arranged in a matrix on the substrate. The shape and layout of pixels directly affect the delicacy of the screen display. The pixel layout of existing technologies is prone to presenting graininess, thereby reducing the display quality of the display panel.

### SUMMARY

One embodiment of the present disclosure is directed to a display panel for improving the problem of graininess in the pixel layout of the display panel in the prior art.

One embodiment of the present disclosure is directed to a display panel. The display panel includes a plurality of pixel repeating units. Each of the pixel repeating units includes a first repeating unit. The first repeating unit includes a first sub-pixel, a second sub-pixel, and two third sub-pixels for displaying different colors. In the first repeating unit, a center of the first sub-pixel, a center of the second sub-pixel, and centers of the two third sub-pixel form a first virtual quadrilateral, with the two third sub-pixels located at diagonal corners of the first virtual quadrilateral.

Optionally, the first repeating units are arranged along a first direction and a second direction. Along the first direction, the first sub-pixel and one of the two third sub-pixels in the first repeating unit are arranged to form a first pixel column, the other of the two third sub-pixels and the second sub-pixel are arranged to form a second pixel column. Along the second direction, the first sub-pixel and one of the two third sub-pixels in the repeating unit are arranged to form a first pixel row, the other of the two third sub-pixels and the second sub-pixel are arranged to form a second pixel row. The first pixel column and the second pixel column are arranged along the second direction, and the first pixel row and the second pixel row are arranged along the first direction.

Optionally, in the first repeating unit, along the first direction, a first spacing is disposed between the first sub-pixel and the third sub-pixel in the first pixel column, and a second spacing is disposed between the third sub-pixel and the second sub-pixel in the second pixel column. Along the second direction, a third spacing is disposed between the first sub-pixel and the third sub-pixel in the first pixel row, and a fourth spacing is disposed between the third sub-pixel and the second sub-pixel in the second pixel row. The first spacing, the second spacing, the third spacing, and the fourth spacing are equal.

Optionally, along the first direction, a spacing disposed between two adjacent first repeating units is equal to the first spacing. A spacing disposed between two adjacent first repeating units in the second direction is equal to the first spacing.

Optionally, the pixel repeating unit further comprises a second repeating unit that comprises a first sub-pixel, a second sub-pixel, and two third sub-pixels. The first repeating unit and the second repeating unit are arranged alternately in the first direction. A center of the first sub-pixel of the second repeating unit, a center of the second sub-pixel of the second repeating unit, and centers of the two third sub-pixels of the second repeating unit form a second virtual quadrilateral, and the two third sub-pixels are respectively located at two diagonal corners of the second virtual quadrilateral.

Optionally, a virtual line extending in the first direction passes through the third sub-pixel in the first repeating unit and the third sub-pixel in the second repeating unit.

Optionally, along the first direction, one of the two third sub-pixels in the first repeating unit and one of the two third sub-pixels in the second repeating unit are adjacent to each other.

Optionally, along the first direction, the first sub-pixel of the first repeating unit, one of the two third sub-pixels of the first repeating unit, one of the two third sub-pixels of the second repeating unit, and the second sub-pixel of the second repeating unit are arranged alternately to form a first pixel column. Along the first direction, one of the two third sub-pixels of the first repeating unit, the second sub-pixel of the first repeating unit, the first sub-pixel of the second repeating unit, and one of the two third sub-pixels of the second repeating unit are arranged alternately to form a second pixel column, the first pixel column and the second pixel column are arranged along the second direction, and the first direction intersects with the second direction.

Optionally, along the first direction, the first sub-pixel of the first repeating unit, one of the two third sub-pixels of the first repeating unit, one of the two third sub-pixels of the second repeating unit, and the first sub-pixel of the second repeating unit are arranged alternately to form a first pixel column. Along the first direction, one of the two third sub-pixels of the first repeating unit, the second sub-pixel of the first repeating unit, one of the two third sub-pixels of the second repeating unit, and the first sub-pixel of the second repeating unit are arranged alternately to form a second pixel column. The first pixel column and the second pixel column are arranged along the second direction.

Optionally, in the first repeating unit, along the second direction, the first sub-pixel and one of the third sub-pixel are arranged to form a first pixel row, and the other of the two third sub-pixels and the second sub-pixel are arranged to form a second pixel row. In the second repeating unit, along the second direction, the first sub-pixel and one of the third sub-pixels are arranged to form a third pixel row, and the other of the two third sub-pixels and the second sub-pixel are arranged to form a fourth pixel row.

Optionally, in the first repeating unit, along the first direction, a first spacing is disposed between the first sub-pixel and the one of the third sub-pixel in the first pixel column, and a second spacing is disposed between the other of the two third sub-pixels and the second sub-pixel in the second pixel column; in the first repeating unit, along the second direction, a third spacing is disposed between the first sub-pixel and one of the two third sub-pixels in the first pixel row, and a fourth spacing is disposed between one of the two third sub-pixels and the second sub-pixel in the second pixel row. The first spacing, the second spacing, the third spacing, and the fourth spacing are equally spaced.

Optionally, in the second repeating unit, along the first direction, a fifth spacing disposed between the second sub-pixel and one of the two third sub-pixels in the first pixel column, and a sixth spacing is disposed between one of the two third sub-pixels and the first sub-pixel in the second pixel column. In the second repeating unit, along the second direction, a seventh spacing disposed between the first sub-pixel and one of the two third sub-pixels in the third pixel row, and an eighth spacing is disposed between one of the two third sub-pixels and the second sub-pixel in the fourth pixel row. The fifth spacing, the sixth spacing, the seventh spacing, and the eighth spacing are equal.

Optionally, the first spacing is equal to the fifth spacing.

Optionally, along the first direction, the spacing disposed between adjacent the first repeating units and the second repeating units is equal to the first spacing.

Optionally, the display panel further includes an anode layer which comprises a plurality of anode portions. Each of the first sub-pixel and the second sub-pixels correspond to one of the anode portions, and the two third sub-pixels located in the first repeating unit share one of the anode portions.

Optionally, the two third sub-pixels located in the second repeating unit share one of the anode portions.

Optionally, the first virtual quadrilateral and the second virtual quadrilateral are parallelograms.

Optionally, the first sub-pixel is a red sub-pixel, the second sub-pixel is a green sub-pixel, and the two third sub-pixels are blue sub-pixels; or the first sub-pixel is a green sub-pixel, the second sub-pixel is a red sub-pixel, and the two third sub-pixels are blue sub-pixels.

Optionally, an area of the first sub-pixel is larger than an area of the third sub-pixel, and an area of the second sub-pixel is larger than an area of the third sub-pixel.

One embodiment of the present disclosure is directed to a display panel. The display panel includes a plurality of pixel repeating units. Each of the pixel repeating units includes a first repeating unit. The first repeating unit includes a first sub-pixel, a second sub-pixel, and two third sub-pixels for displaying different colors. In the first repeating unit, a center of the first sub-pixel, a center of the second sub-pixel, and centers of the two third sub-pixel form a first virtual quadrilateral, with the two third sub-pixels located at diagonal corners of the first virtual quadrilateral. The present disclosure proposes a new pixel layout, improving the graininess of the pixels in the display panel and the display quality of the display panel.

### BRIEF DESCRIPTION OF THE DRAWINGS

To describe the technical solutions in the embodiments of the present disclosure more clearly, the following briefly introduces the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a first planar schematic diagram of a display panel according to one embodiment of the present disclosure.

FIG. 2 is a cross-sectional schematic diagram of the display panel taken along the A-A′ direction of FIG. 1.

FIG. 3 is a cross-sectional schematic diagram of the display panel taken along the B-B′ direction in FIG. 1.

FIG. 4 is a second planar schematic diagram of the display panel according to one embodiment of the present disclosure.

FIG. 5 is a third planar schematic diagram of the display panel according to one embodiment of the present disclosure.

### DESCRIPTION OF THE EMBODIMENTS

To help a person skilled in the art better understand the solutions of the present disclosure, the following clearly and completely describes the technical solutions in the embodiments of the present invention with reference to the accompanying drawings in the embodiments of the present invention. Apparently, the described embodiments are a part rather than all of the embodiments of the present invention. All other embodiments obtained by a person of ordinary skill in the art based on the embodiments of the present invention without creative efforts shall fall within the protection scope of the present disclosure.

The term “first”, “second” are for illustrative purposes only and are not to be construed as indicating or imposing a relative importance or implicitly indicating the number of technical features indicated. Thus, a feature that limited by “first”, “second” may expressly or implicitly include at least one of the features.

In the description of the present disclosure, the meaning of “plural” is two or more, unless otherwise specifically defined.

Throughout the specification and claims, when it is described that an element is “connected” to another element, the element may be “directly connected” to the other element, or “electrically connected” to the other element through a third element.

Furthermore, the term “comprising” will be understood as meaning the inclusion of elements but not the exclusion of any other elements, unless explicitly described to the contrary.

The following disclosure provides many different embodiments or examples to implement different structures of the present disclosure. In order to simplify the disclosure of the present disclosure, the components and settings of specific examples are described below. They are for example purposes only and are not intended to limit this application. Further, the present disclosure may repeat reference numbers and/or reference letters in different examples, such duplication is for the purpose of simplification and clarity, and does not by itself indicate the relationship between the various embodiments and/or settings discussed. Further, the present disclosure provides various examples of specific processes and materials, but those of ordinary skill in the art may be aware of the application of other processes and/or the use of other materials. The following are described in detail, it should be noted that the order of description of the following embodiments is not used as a qualification for the preferred order of embodiments.

One embodiment of the present disclosure is directed to a display panel. The display panel includes a plurality of pixel repeating units. Each of the pixel repeating units includes a first repeating unit. The first repeating unit includes a first sub-pixel, a second sub-pixel, and two third sub-pixels for displaying different colors. In the first repeating unit, a center of the first sub-pixel, a center of the second sub-pixel, and centers of the two third sub-pixel form a first virtual quadrilateral, with the two third sub-pixels located at diagonal corners of the first virtual quadrilateral.

The present disclosure proposes a new pixel layout, improving the graininess of the pixels in the display panel and the display quality of the display panel.

The display panel provided by the present disclosure will be described in detail below through specific embodiments.

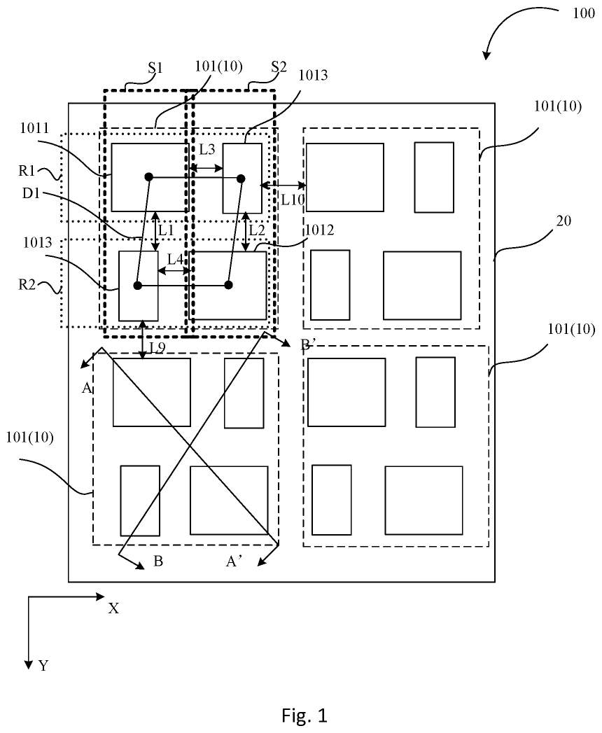

Please refer to FIG. 1 illustrating a first planar schematic diagram of a display panel according to one embodiment of the present disclosure. The display panel 100 comprises a plurality of pixel repeating units 10. Each of the pixel repeating units 10 comprises a first repeating unit 101. The first repeating unit 101 comprises a first sub-pixel 1011, a second sub-pixel 1012, and two third sub-pixels 1013 for displaying different colors. Among them, in the first repeating unit 101, a center of the first sub-pixel 1011, a center of the second sub-pixel 1012, and a center of the third sub-pixel 1013 form a first virtual quadrilateral D1, with the two third sub-pixels 1013 located at the diagonal corners of the first virtual quadrilateral D1.

The center of each of the sub-pixels according to one embodiment of the present disclosure can be the geometric center of the sub-pixel shape.

In some embodiments, the shapes of the first sub-pixel 1011, the second sub-pixel 1012, and the third sub-pixel 1013 may be any of circular, rectangular, parallelogram, or trapezoidal shapes. This embodiment of the present disclosure uses a rectangle as an example for explanation, but is not limited thereto.

In this embodiment of the present disclosure, the different planar arrangement of a plurality of pixel repeating units 10 constitutes the pixel arrangement provided in the embodiment of the present disclosure. The arrangement of each of the sub-pixels in the embodiment of the present disclosure can be understood as the planar arrangement of each of the sub-pixels.

The first repeating unit 101 in the embodiment of the present disclosure can be regarded as a pixel unit. Unlike pixel units of known techniques, the first repeating unit 101 in the embodiment of the present disclosure comprises a first sub-pixel 1011, a second sub-pixel 1012, and two third sub-pixels 1013, and the third sub-pixel 1013 is respectively arranged at the diagonal corners of the first virtual quadrilateral D1 through the pixel arrangement method mentioned above, to arrange the sub-pixels as closely as possible, improve the graininess of the pixels on the display panel 100, enhance visual resolution, and thus improve the display quality of the display panel 100.

In the embodiment of the present disclosure, a plurality of first repeating units 101 are arranged along the first direction Y and the second direction X. The first direction Y intersects with the second direction X.

The first direction Y and the second direction X in the embodiment of the present disclosure have an angle, and the angle disposed between the first direction Y and the second direction X ranges from 0 degrees to 180 degrees. The embodiment of the present disclosure takes the angle disposed between the first direction Y and the second direction X as an example but is not limited to this.

In the first repeating unit 101, along the first direction Y, the first sub-pixel 1011 and the third sub-pixel 1013 are arranged to form the first pixel column S1, the third sub-pixel 1013 and the second sub-pixel 1012 are arranged to form the second pixel column S2, and the first pixel column S1 and the second pixel column S2 are arranged along the second direction X. Along the second direction X, the first sub-pixel 1011 and the third sub-pixel 1013 are arranged to form the first pixel row R1, the third sub-pixel 1013 and the second sub-pixel 1012 are arranged to form the second pixel row R2, and the first pixel row R1 and the second pixel row R2 are arranged along the first direction Y.

It should be understood that the first repeating unit 101 in the embodiment of the present disclosure can be regarded as a pixel unit. Unlike pixel units in known techniques, the pixel unit of the present disclosure comprises a first sub-pixel 1011, a second sub-pixel 1012, and two third sub-pixels 1013. By setting the two third sub-pixels 1013 on the diagonal corners of the first virtual quadrilateral D1, By increasing the emission range of the two third sub-pixels 1013, this pixel layout method improves the graininess of the pixels on the display panel 100, thereby improving the display quality of the display panel 100.

In the pixel layout structure of display panel 100, the sub-pixel arrangement mentioned forms a row or column of pixels, referring to the range of positions where the sub-pixels are located. As long as the sub-pixels located in the same pixel column are within the dashed box extending in the first direction Y, and the sub-pixels located in the same pixel row are within the dashed box extending in the second direction X. In a specific implementation, the centers of sub-pixels located in the same row can be located on the same line. Of course, the centers of sub-pixels can also be different from the same line, meaning that there is an offset in the center of sub-pixels, which is not limited here.

The line formed by the center of the first sub-pixel 1011 of the first pixel column S1 and the center of the third sub-pixel 1013 can be parallel or not parallel to the first direction Y. The line formed by the center of the second sub-pixel 1012 and the center of the third sub-pixel 1013 in the second pixel column S2 can be parallel to or not parallel to the first direction Y. The line formed by the center of the first sub-pixel 1011 and the center of the third sub-pixel 1013 in the first pixel row R1 can be parallel to or not parallel to the second direction X. The third sub-pixel 1013 and second sub-pixel 1012 in the second pixel row R2 can be parallel to or not parallel to the second direction X. There are no restrictions here.

In the first repeating unit 101, along the first direction Y, the spacing disposed between the first sub-pixel 1011 and the third sub-pixel 1013 is the first spacing L1, and the spacing disposed between the third sub-pixel 1013 and the second sub-pixel 1012 is the second spacing L2. Along the second direction X, the spacing disposed between the first sub-pixel 1011 and the third sub-pixel 1013 is the third spacing L3, and the spacing disposed between the third sub-pixel 1013 and the second sub-pixel 1012 is the fourth spacing L4. Among them, the first spacing L1, the second spacing L2, the third spacing L3, and the fourth spacing L4 are equal.

In the embodiment provided in the present disclosure, along the first direction Y, the spacing L9 disposed between two adjacent first repeating units 101 is equal to the first spacing L1. Along the second direction X, the spacing L10 disposed between two adjacent first repeating units 101 is equal to the first spacing L1.

The spacing disposed between each of the sub-pixels mentioned in the pixel layout structure of the display panel 100 provided in the embodiment of the present disclosure refers to the shortest spacing disposed between the edges of each of the sub-pixels that are close to each other.

The first spacing L1, second spacing L2, third spacing L3, and fourth spacing L4 of the present disclosure embodiment are equal, and along the first direction Y, the spacing disposed between adjacent first repeating units 101 is equal to the first spacing L1. Along the second direction X, the spacing disposed between two adjacent first repeating units 101 is equal to the first spacing L1. Making the arrangement of sub-pixels more uniform is beneficial for improving display quality. On the other hand, it can effectively avoid the occurrence of aliasing or interference between adjacent sub-pixels.

The spacings referred to in the embodiments of the present disclosure are equal and not necessarily completely equal. Due to the influence of process errors, there may be certain errors between the spacings. The allowable error range for two different spacings of the same first repeating unit 101 is ±10%.

In the embodiment of the present disclosure, the first virtual quadrilateral D1 is a parallelogram.

In another embodiment, the first virtual quadrilateral D1 can also be a rectangle, isosceles trapezoid, or irregular quadrilateral. The present disclosure takes the first virtual quadrilateral D1 as a parallelogram as an example, but is not limited to this.

The first sub-pixel 1011 is a red sub-pixel, the second sub-pixel 1012 is a green sub-pixel, and the third sub-pixel 1013 is a blue sub-pixel. Alternatively, the first sub-pixel 1011 is a green sub-pixel, the second sub-pixel 1012 is a red sub-pixel, and the third sub-pixel 1013 is a blue sub-pixel. The area of the first sub-pixel 1011 is greater than the area of the third sub-pixel 1013, and the area of the second sub-pixel 1012 is greater than the area of the third sub-pixel 1013.

Sub-pixels with different colors generally have different lifespans, so the area of the sub-pixel can be set based on its lifespan. Generally, the area of the sub-pixel with the lowest lifespan is set to the maximum.

Due to the lowest service life of blue sub-pixels among current organic luminescent materials, it is optional that in the pixel layout structure of the display panel 100 provided in the present disclosure embodiment, the sum of the areas of two third sub-pixels 1013 in the same first repeating unit 101 is greater than the area of a first sub-pixel 1011 or a second sub-pixel 1012.

In the pixel layout structure of display panel 100, the area of the first sub-pixel 1011 can be equal to the area of the second sub-pixel 1012. The area of the first sub-pixel 1011 can also be set to be greater than the area of the second sub-pixel 1012, or the area of the second sub-pixel 1012 can be set to be greater than the area of the first sub-pixel 1011.

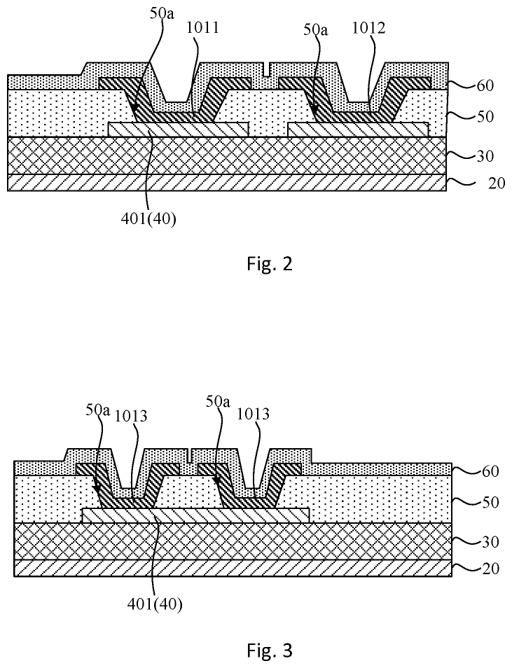

Please refer to FIGS. 2 and 3, which are a cross-sectional schematic diagram of the display panel taken along the A-A′ direction of FIG. 1 and a cross-sectional schematic diagram of the display panel taken along the B-B′ direction in FIG. 1. The display panel 100 also comprises a substrate 20, a driving function layer 30, an anode layer 40, a pixel definition layer 50, and a cathode layer 60. Among them, the driving function layer 30 is set on the substrate 20. The anode layer 40 is arranged on the side of the driving functional layer 30 away from the substrate 20, and is connected to the driving functional layer 30. The anode layer 40 comprises a plurality of anode parts 401. The pixel definition layer 50 is located on the side of the driving function layer 30 away from the substrate 20. The pixel definition layer 50 has a plurality of openings 50a, each of which comprises a portion of the surface of the anode portion 401. A first sub-pixel 1011 and a second sub-pixel 1012 are respectively arranged within an opening 50a, and correspond to an anode portion 401. A third sub-pixel 1013 is arranged within an opening 50a, and two third sub-pixels 1013 within the first repeating unit 101 share an anode portion 401. The cathode layer 60 is set on the side of the pixel definition layer 50 away from the array substrate 20, and covers the first sub-pixel 1011, the second sub-pixel 1012, and the third sub-pixel 1013.

The driving function layer 30 comprises functional layers such as driver transistors to drive each of the sub-pixels to emit light normally. For example, the driving functional layer 30 comprises a light-blocking layer set on the substrate 20, a buffer layer set on the substrate 20 and covered with the light-blocking layer, an active layer, gate insulation layer, and gate arranged on the buffer layer from bottom to top, and an interlayer dielectric layer set above the buffer layer and covered with the active layer, a gate insulation layer, and a gate. Among them, the active layer comprises the channel region, as well as the source and drain regions located on both sides of the channel region. The source electrode and source electrode area are electrically connected on the interlayer dielectric layer. The drain and drain area are electrically connected to the interlayer dielectric layer. The source and drain electrodes can also be covered with stacked passivation layers and/or flattening layers. The anode layer 40 is arranged on the passivation layer or the flattening layer.

Two third sub-pixels 1013 located within the same first repeating unit 101 share a common anode portion 401, increasing the emission range of the third sub-pixel 1013, improving the graininess of the pixels in the display panel 100, and thereby improving the display quality of the display panel 100.

In another embodiment, the two third sub-pixels 1013 located in the same first repeating unit 101 can also be respectively set on one anode section 401, that is, the two third sub-pixels 1013 in the same first repeating unit 101 can be driven separately, so that the adjacent two first repeating units 101 can share sub-pixels, thereby improving the resolution of the display panel 100.

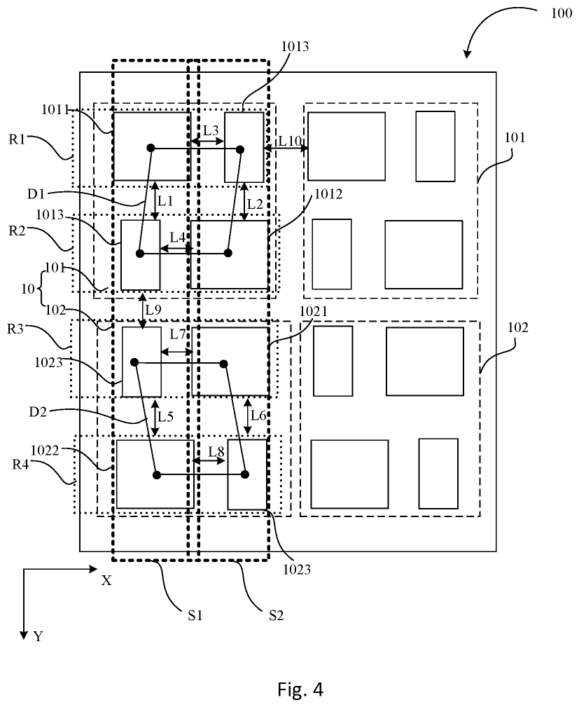

Please refer to FIG. 4, which is a second planar schematic diagram of the display panel according to one embodiment of the present disclosure. The difference between the display panel 100 in FIG. 4 and the display panel 100 provided in FIG. 1 is that the pixel repeating unit 10 also comprises a second repeating unit 102, with the first repeating unit 101 and the second repeating unit 102 arranged in the first direction Y. The second repeating unit 102 comprises a first sub-pixel 1011, a second sub-pixel 1012, and two third sub-pixels 1013. Among them, the center of one first sub-pixel 1011, one second sub-pixel 1012, and two third sub-pixels 1013 in the second repeating unit 102 form the second virtual quadrilateral D2, with the two third sub-pixels 1013 located at the diagonal corners of the second virtual quadrilateral D2.

The second repeating unit 102 can be regarded as a pixel unit. Unlike pixel units in known techniques, the first second repeating unit 102 of the present disclosure embodiment comprises a first sub-pixel 1021, a second sub-pixel 1022, and two third sub-pixels 1023, and the two third sub-pixels 1023 are respectively arranged at the diagonal corners of the second virtual quadrilateral D2. By using the pixel arrangement method mentioned above, the sub-pixels are arranged as closely as possible, improving the graininess of pixels on display panel 100, enhancing visual resolution, and thus improving the display quality of display panel 100.

The virtual line extending in the first direction Y passes through the third sub-pixel 1013 in the first repeating unit 101 and the third sub-pixel 1023 in the second repeating unit 102. It can be understood that a virtual straight line parallel to the first direction Y passes through the third sub-pixel 1013 in the first repeating unit 101 and the third sub-pixel 1023 in the second repeating unit 102 simultaneously, that is, along the first direction Y, at least part of the third sub-pixel 1013 in the first repeating unit 101 and the third sub-pixel 1023 in the second repeating unit 102 correspond to the setting.

The embodiment provided in the present disclosure refers to a virtual line parallel to the first direction Y that simultaneously passes through the third sub-pixel 1013 in the first repeating unit 101 and the third sub-pixel 1023 in the second repeating unit 102. It can be understood that the virtual line passes through the third sub-pixel 1013 in the first repeating unit 101 and the third sub-pixel 1023 in the second repeating unit 102 on the plane where each of the sub-pixels is located.

Furthermore, along the first direction Y, a third sub-pixel 1013 in the first repeating unit 101 and a third sub-pixel 1023 in the second repeating unit 102 are adjacent to each other.

Along the first direction Y, the first sub-pixel 1011, a third sub-pixel 1013, a third sub-pixel 1023, and a second sub-pixel 1022 in the first repeating unit 101 are arranged alternately to form the first pixel column S1. Along the first direction Y, a third sub-pixel 1013 and a second sub-pixel 1012 in the first repeating unit 101 are arranged alternately with the first sub-pixel 1021 and a third sub-pixel 1023 in the second repeating unit 102 to form a second pixel column S2. The first pixel column S1 and the second pixel column S2 are arranged in the second direction X.

In the embodiment of the present disclosure, the centers of each of the sub-pixels located in the first pixel column S1 or the second pixel column S2 are on the same line, and the extension direction of the line is the same as the first direction Y. Alternatively, in the first pixel column S1 or the second pixel column S2, the extension direction of the line formed by the center of the third sub-pixel 1013 of the first repeating unit 101 and the center of the third sub-pixel 1023 of the second repeating unit 102 is the same as the first direction Y. The extension direction of the line formed by the center of the first sub-pixel 1011 of the first repeating unit 101 and the center of the second sub-pixel 1022 of the second repeating unit 102 is the same as the first direction Y.

In the first repeating unit 101, the first sub-pixel 1011 and the third sub-pixel 1013 are arranged along the second direction X to form the first pixel row R1, while the third sub-pixel 1013 and the second sub-pixel 1012 are arranged along the second direction X to form the second pixel row R2. In the second repeating unit 102, the first sub-pixel 1021 and the third sub-pixel 1023 are arranged along the second direction X to form a third pixel row R3, the third sub-pixel 1023 and the second sub-pixel 1022 are arranged along the second direction X to form a fourth pixel row R4, and the first pixel row R1, the second pixel row R2, the third pixel row R3, and the fourth pixel row R4 are arranged in sequence along the first direction Y.

There are adjacent first repeating units 101 and second repeating units 102 arranged in the first direction Y. Since the second pixel row R2 comprises the third sub-pixel 1013 and the second sub-pixel 1012, and the third pixel row R3 comprises the first sub-pixel 1021 and the third sub-pixel 1023, it can be considered that the sub-pixels of the second pixel row R2 and the third pixel row R3 can also form a pixel unit, The arrangement of pixels mentioned above can improve the resolution of pixels in the display panel 100.

The line formed by the centers of the first sub-pixel 1011 and the third sub-pixel 1013 in the first pixel row R1 is parallel to or not parallel to the second direction X. The line formed by the center of the third and second sub-pixels 1013 and 1012 in the second pixel row R2 is parallel to or not parallel to the second direction X. The line formed by the centers of the first sub-pixel 1021 and the third sub-pixel 1023 in the third pixel row R3 is parallel to or not parallel to the second direction X. The line formed by the centers of the third and second sub-pixels 1023 and 1022 in the fourth pixel row R4 is parallel or not parallel to the second direction X, and is not limited here.

In the above pixel layout structure provided in the implementation example of the present disclosure, the vertical and parallel mentioned are not completely vertical or parallel, but have a certain error range of ±5°, that is, the two are perpendicular to each other refers to the angle disposed between the two is greater than or equal to 85° and less than or equal to 95°, that is, the two are parallel to each other refers to the angle disposed between the two is greater than or equal to −5° and less than or equal to +5°.

In the embodiment of the present disclosure, the second virtual quadrilateral D2 is a parallelogram.

The second virtual quadrilateral D2 can also be a rectangle, isosceles trapezoid, or irregular quadrilateral. The present disclosure takes the second virtual quadrilateral D2 as a parallelogram as an example, but is not limited to this.

In the second repeating unit 102, along the first direction Y, the spacing disposed between the second sub-pixel 1022 and the third sub-pixel 1023 is the fifth spacing L5, and the spacing disposed between the third sub-pixel 1023 and the first sub-pixel 1021 is the sixth spacing L6. Along the second direction X, the spacing disposed between the first sub-pixel 1021 and the third sub-pixel 1023 is the seventh spacing L7, and the spacing disposed between the third sub-pixel 1023 and the second sub-pixel 1022 is the eighth spacing L8. Among them, the fifth spacing L5, sixth spacing L6, seventh spacing L7, and eighth spacing L8 are equal.

Along the first direction Y, the spacing L9 between the adjacent first repeating unit 101 and second repeating unit 102 is equal to the first spacing L1.

The first spacing L1 is equal to the fifth spacing L5.

The fifth spacing L5, sixth spacing L6, seventh spacing L7, and eighth spacing L8 in the embodiment of the present disclosure are equal, making the arrangement of sub-pixels more uniform, which is conducive to improving display quality. On the other hand, it can effectively avoid the occurrence of jagged color or interference between adjacent sub-pixels.

The two third sub-pixels 1023 located in the second repeating unit 102 share the same anode section 401. Increase the emission range of the third sub-pixel 1023, improve the graininess of the pixels on the display panel 100, and thus improve the display quality of the display panel 100.

The two third sub-pixels 1023 located in the same second repeating unit 102 can also be respectively set on one anode section 401, that is, the two third sub-pixels 1023 in the same second repeating unit 102 can be driven separately, so that adjacent first repeating unit 101 and second repeating unit 102 can share sub-pixels, thereby improving the resolution of the display panel 100.

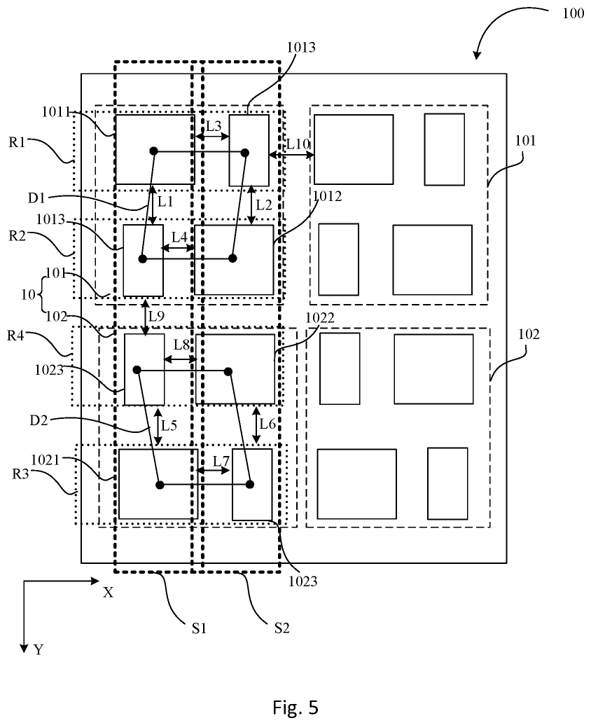

Please refer to FIG. 5, which is a third planar schematic diagram of the display panel according to one embodiment of the present disclosure. The difference between the display panel in FIG. 5 and the display panel provided in FIG. 4 is that along the first direction Y, the first sub-pixel 1011, the third sub-pixel 1013 in the first repeating unit 101, and the third sub-pixel 1023, the first sub-pixel 1021 in the second repeating unit 102 are alternately arranged to form the first pixel column S1. Along the first direction Y, a third sub-pixel 1013, a second sub-pixel 1012, a second sub-pixel 1022, and a third sub-pixel 1023 in the first repeating unit 101 are alternately arranged to form a second pixel column S2. In the embodiment of the present disclosure, the first pixel row R1, the second pixel row R2, the fourth pixel row R4, and the third pixel row R3 are arranged in the first direction Y.

The two third sub-pixels 1013 in the first repeating unit 101 are located at the diagonal corners of the first virtual quadrilateral D1, and the two third sub-pixels 1013 in the second repeating unit 102 are located at the diagonal corners of the second virtual quadrilateral D2. By using the above pixel layout method, the sub-pixels are arranged as closely as possible to improve the graininess of the pixels on display panel 100, enhance visual resolution, and thus improve the display quality of display panel 100.

The above is a display device provided by an embodiment of the present disclosure is described in detail, and a specific example is applied herein to explain the principle and embodiment of the present disclosure, and the description of the above embodiment is only used to help understand the method of the present disclosure and its core ideas. At the same time, for those skilled in the art, according to the idea of the present disclosure, there will be changes in the specific embodiment and the scope of application, in summary, the content of this specification should not be understood as a restriction on the present disclosure.

What is claimed is:

1. A display panel, comprising:
a plurality of pixel repeating units, each of the pixel repeating units comprising a first repeating unit that comprises a first sub-pixel, a second sub-pixel, and two third sub-pixels for displaying different colors,
wherein in the first repeating unit, a center of the first sub-pixel, a center of the second sub-pixel, and centers of the two third sub-pixel form a first virtual quadrilateral, with the two third sub-pixels located at diagonal corners of the first virtual quadrilateral.

2. The display panel as claimed in claim 1, wherein the first repeating units are arranged along a first direction and a second direction;
along the first direction, the first sub-pixel and one of the two third sub-pixels in the first repeating unit are arranged to form a first pixel column, the other of the two third sub-pixels and the second sub-pixel are arranged to form a second pixel column, and;
along the second direction, the first sub-pixel and one of the two third sub-pixels in the repeating unit are arranged to form a first pixel row, the other of the two third sub-pixels and the second sub-pixel are arranged to form a second pixel row;
the first pixel column and the second pixel column are arranged along the second direction, and the first pixel row and the second pixel row are arranged along the first direction.

3. The display panel as claimed in claim 2, wherein in the first repeating unit, along the first direction, a first spacing is disposed between the first sub-pixel and the third sub-pixel in the first pixel column, and a second spacing is disposed between the third sub-pixel and the second sub-pixel in the second pixel column; along the second direction, a third spacing is disposed between the first sub-pixel and the third sub-pixel in the first pixel row, and a fourth spacing is disposed between the third sub-pixel and the second sub-pixel in the second pixel row; and the first spacing, the second spacing, the third spacing, and the fourth spacing are equal.

4. The display panel as claimed in claim 3, wherein along the first direction, a spacing disposed between two adjacent first repeating units is equal to the first spacing; a spacing disposed between two adjacent first repeating units in the second direction is equal to the first spacing.

5. The display panel as claimed in claim 1, wherein the pixel repeating unit further comprises a second repeating unit that comprises a first sub-pixel, a second sub-pixel, and two third sub-pixels; the first repeating unit and the second repeating unit are arranged alternately in the first direction; a center of the first sub-pixel of the second repeating unit, a center of the second sub-pixel of the second repeating unit, and centers of the two third sub-pixels of the second repeating unit form a second virtual quadrilateral, and the two third sub-pixels are respectively located at two diagonal corners of the second virtual quadrilateral.

6. The display panel as claimed in claim 5, wherein a virtual line extending in the first direction passes through the third sub-pixel in the first repeating unit and the third sub-pixel in the second repeating unit.

7. The display panel as claimed in claim 6, wherein along the first direction, one of the two third sub-pixels in the first repeating unit and one of the two third sub-pixels in the second repeating unit are adjacent to each other.

8. The display panel as claimed in claim 7, wherein along the first direction, the first sub-pixel of the first repeating unit, one of the two third sub-pixels of the first repeating unit, one of the two third sub-pixels of the second repeating unit, and the second sub-pixel of the second repeating unit are arranged alternately to form a first pixel column;
along the first direction, one of the two third sub-pixels of the first repeating unit, the second sub-pixel of the first repeating unit, the first sub-pixel of the second repeating unit, and one of the two third sub-pixels of the second repeating unit are arranged alternately to form a second pixel column, the first pixel column and the second pixel column are arranged along the second direction, and the first direction intersects with the second direction.

9. The display panel as claimed in claim 7, wherein along the first direction, the first sub-pixel of the first repeating unit, one of the two third sub-pixels of the first repeating unit, one of the two third sub-pixels of the second repeating unit, and the first sub-pixel of the second repeating unit are arranged alternately to form a first pixel column;
along the first direction, one of the two third sub-pixels of the first repeating unit, the second sub-pixel of the first repeating unit, one of the two third sub-pixels of the second repeating unit, and the first sub-pixel of the second repeating unit are arranged alternately to form a second pixel column;
the first pixel column and the second pixel column are arranged along the second direction.

10. The display panel as claimed in claim 8, wherein in the first repeating unit, along the second direction, the first sub-pixel and one of the third sub-pixel are arranged to form a first pixel row, and the other of the two third sub-pixels and the second sub-pixel are arranged to form a second pixel row; in the second repeating unit, along the second direction, the first sub-pixel and one of the third sub-pixels are arranged to form a third pixel row, and the other of the two third sub-pixels and the second sub-pixel are arranged to form a fourth pixel row.

11. The display panel as claimed in claim 10, wherein in the first repeating unit, along the first direction, a first spacing is disposed between the first sub-pixel and the one of the third sub-pixel in the first pixel column, and a second spacing is disposed between the other of the two third sub-pixels and the second sub-pixel in the second pixel column; in the first repeating unit, along the second direction, a third spacing is disposed between the first sub-pixel and one of the two third sub-pixels in the first pixel row, and a fourth spacing is disposed between one of the two third sub-pixels and the second sub-pixel in the second pixel row;
the first spacing, the second spacing, the third spacing, and the fourth spacing are equally spaced.

12. The display panel as claimed in claim 11, wherein in the second repeating unit, along the first direction, a fifth spacing disposed between the second sub-pixel and one of the two third sub-pixels in the first pixel column, and a sixth spacing is disposed between one of the two third sub-pixels and the first sub-pixel in the second pixel column; in the second repeating unit, along the second direction, a seventh spacing disposed between the first sub-pixel and one of the two third sub-pixels in the third pixel row, and an eighth spacing is disposed between one of the two third sub-pixels and the second sub-pixel in the fourth pixel row; the fifth spacing, the sixth spacing, the seventh spacing, and the eighth spacing are equal.

13. The display panel as claimed in claim 12, wherein the first spacing is equal to the fifth spacing.

14. The display panel as claimed in claim 13, wherein along the first direction, the spacing disposed between adjacent the first repeating units and the second repeating units is equal to the first spacing.

15. The display panel as claimed in claim 5, further comprising:
an anode layer, comprising a plurality of anode portions, wherein each of the first sub-pixel and the second sub-pixels correspond to one of the anode portions, and the two third sub-pixels located in the first repeating unit share one of the anode portions.

16. The display panel as claimed in claim 15, wherein the two third sub-pixels located in the second repeating unit share one of the anode portions.

17. The display panel as claimed in claim 5, wherein the first virtual quadrilateral and the second virtual quadrilateral are parallelograms.

18. The display panel as claimed in claim 1, wherein the first sub-pixel is a red sub-pixel, the second sub-pixel is a green sub-pixel, and the two third sub-pixels are blue sub-pixels;
or the first sub-pixel is a green sub-pixel, the second sub-pixel is a red sub-pixel, and the two third sub-pixels are blue sub-pixels.

19. The display panel as claimed in claim 1, wherein an area of the first sub-pixel is larger than an area of the third sub-pixel, and an area of the second sub-pixel is larger than an area of the third sub-pixel.

20. A display panel, comprising:
a plurality of pixel repeating units, each of the pixel repeating units comprising: a first sub-pixel for displaying a first color, a second sub-pixel for displaying a second color, a third sub-pixel for displaying a third color, and a fourth sub-pixel for displaying the third color,
wherein a first direction from a center of the first sub-pixel to a center of the third sub-pixel is parallel to a second direction from a center of the second sub-pixel to a center of the fourth sub-pixel, and a third direction from the center of the first sub-pixel to the center of the fourth sub-pixel is parallel to a fourth line from the center of the second sub-pixel to the center of the third sub-pixel, and the first direction is not perpendicular to the third direction.
